(19) United States
(12) Patent Application Publication
(10) Pub. No.: US 2025/0391806 A1
(43) Pub. Date: Dec. 25, 2025

(54) SEMICONDUCTOR PACKAGE AND MANUFACTURING METHOD FOR THE SAME

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/006,396

(22) Filed: Dec. 31, 2024

(30) Foreign Application Priority Data
Jun. 19, 2024 (KR) 10-2024-0079340

(51) Int. Cl. H01L 23/00; H01L 25/00; H01L 25/07; H10B 80/00

(52) U.S. Cl. CPC H01L 24/48; H01L 24/16; H01L 24/24; H01L 24/73; H01L 25/074; H01L 25/50; H01L 2224/16227; H01L 2224/24146; H01L 2224/244; H01L 2224/48106; H01L 2224/48229; H01L 2224/48476; H01L 2224/73227; H01L 2225/06562; H01L 2225/06565; H10B 80/00

(57) ABSTRACT

The present disclosure as at least one embodiment provides a semiconductor package including a semiconductor chip including a connection pad; a conductive pad disposed on the semiconductor chip and spaced apart from the semiconductor chip; a conductive wire in contact with each of the connection pad of the semiconductor chip and the conductive pad, and connecting the connection pad and the conductive pad; an encapsulant that encapsulates at least a portion of each of the semiconductor chip, the conductive pad, and the conductive wire; and a redistribution structure disposed on the encapsulant and including a via in contact with the conductive pad and a wiring layer connected to the via, wherein the diameter of the conductive pad is larger than each diameter of the conductive wire and the via.

### CROSS-REFERENCE TO RELATED APPLICATION

This application claims priority to and the benefit of Korean Patent Application No. 10-2024-0079340 filed in the Korean Intellectual Property Office on Jun. 19, 2024, the entire contents of which are incorporated herein by reference.

### BACKGROUND OF THE DISCLOSURE

### (a) Field of the Disclosure

The present disclosure relates to a semiconductor package and a manufacturing method thereof.

### (b) Description of the Related Art

In a semiconductor industry, a vertical wire bonding may be applied, which bonds wires vertically to a semiconductor chip and connects them to other components of the semiconductor package. The vertical wire bonding technology may be applied to DRAM products of, for example, high performance, high-capacity, and low electric power.

### SUMMARY OF THE DISCLOSURE

In one aspect, the present disclosure seeks to provide a semiconductor package and a manufacturing method thereof that may prevent poor connections by compensating for a sweeping of conductive wires.

The present disclosure as at least one embodiment provides a semiconductor package including a semiconductor chip including a connection pad; a conductive pad over the semiconductor chip, the conductive pad spaced apart from the semiconductor chip; a conductive wire electrically connecting the connection pad of the semiconductor chip with the conductive pad; an encapsulant encapsulating at least a portion of the semiconductor chip, the conductive pad, and the conductive wire; and a redistribution structure on the encapsulant, the redistribution structure including a via and a wiring layer, the via electrically contacting the conductive pad and the wiring layer electrically contacting the via, wherein the diameter of the conductive pad is larger than a diameter of the conductive wire and a diameter of the via.

The present disclosure as at least one embodiment provides a semiconductor package including a stack of semiconductor chips, the stack of semiconductor chips including a first semiconductor chip on the lowest side of the stack of semiconductor chips, the first semiconductor including a first connection pad; a conductive pad over the stack of semiconductor chips such that the conductive pad is spaced apart from the first semiconductor chip; a first conductive wire electrically connecting the first connection pad and the conductive pad; an encapsulant encapsulating at least a portion of each of the stack of semiconductor chips, the conductive pad, and the first conductive wire; and a redistribution structure on the encapsulant, the redistribution structure including a first via in electrical contact with the conductive pad and a wiring layer electrically connected to the first via, wherein a diameter of the conductive pad is larger than a diameter of the conductive wire and a diameter of the via.

The present disclosure as at least one embodiment provides a manufacturing method of a semiconductor package including stacking a plurality of semiconductor chips, each including a connection pad; connecting a conductive wire to at least one connection pad among the plurality of semiconductor chips; encapsulating the plurality of semiconductor chips and the conductive wire with an encapsulant; exposing the conductive wire by grinding the encapsulant; forming a groove portion extending from an upper surface of the encapsulant towards an inside of the encapsulant; forming a conductive pad filling the groove portion such that the conductive pad is electrically connected to the conductive wire; and forming a redistribution structure on the encapsulant, the redistribution structure including a via in electrical contact with the conductive pad and a wiring layer in electrical contact with the via, wherein a diameter of the conductive pad is larger than a diameter of the conductive wire and a diameter of the via.

According to one aspect of the present disclosure, the semiconductor package and the manufacturing method thereof that may prevent and/or reduce the potential for poor connections by compensating for the sweeping of the conductive wires.

### BRIEF DESCRIPTION OF THE DRAWINGS

FIG. 1 is a cross-sectional view of a semiconductor package according to at least one embodiment.

FIG. 2 is an enlarged view of a region A in FIG. 1.

FIG. 3 is a detailed view of a region A of FIG. 1.

FIG. 4 is a detailed view according to an example variation of a region A in FIG. 1.

FIG. 5 is a detailed view according to another example variation of a region A in FIG. 1.

FIG. 6 is a cross-sectional view of a semiconductor package according to at least one embodiment.

FIG. 7 to FIG. 15 are views showing a manufacturing process of a semiconductor package according to at least one embodiment.

FIG. 16 is a cross-sectional view of a package on package (POP) including a semiconductor package according to at least one embodiment.

FIG. 17 is a cross-sectional view of another package including a semiconductor package according to at least one embodiment.

FIG. 18 is a cross-sectional view of a package on board including a semiconductor package according to at least one embodiment.

### DETAILED DESCRIPTION OF THE EMBODIMENTS

Hereinafter, several example embodiments of the present disclosure will be described in detail with reference to the accompanying drawings so that those skilled in the art to which the present disclosure pertains may easily practice the present disclosure. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification, therefore repeat descriptions thereof may be omitted for brevity.

Further, in the drawings, a size and thickness of each element are randomly represented for better understanding and ease of description, and the present disclosure is not limited thereto. In the drawings, the thickness of layers, films, panels, regions, etc., may be exaggerated for clarity. For example, in the drawings, for understanding and ease of description, the thickness of some layers and areas is exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “C to D”, this means C inclusive to D inclusive unless otherwise specified.

Throughout this specification and the claims that follow, when it is described that an element is “coupled” to another element, the element may be “directly coupled” to the other element or “indirectly coupled” to the other element through a third element. In a similar sense, this includes being “physically coupled” as well as being “electrically coupled”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

Additionally, throughout the specification, sequential numbers such as first and second are used to distinguish a component from other components that are the same or similar to it, and are not necessarily intended to refer to a specific component. Accordingly, a component referred to as a first component in a specific part of this specification may also be referred to as a second component in other parts of this specification.

Additionally, throughout the specification, references to any component in the singular include references to the plurality of these components, unless specifically stated to the contrary. For example, “insulating layer” may be used to mean not only one insulating layer, but also a plurality of insulating layers, such as two, three or more.

Hereinafter, a semiconductor package and a manufacturing method thereof according to embodiments of the present disclosure will be described with reference to the drawing.

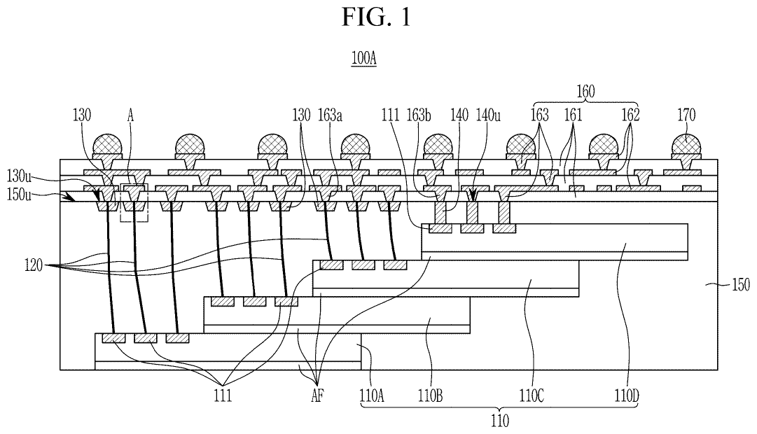

FIG. 1 is a cross-sectional view of a semiconductor package according to at least one embodiment.

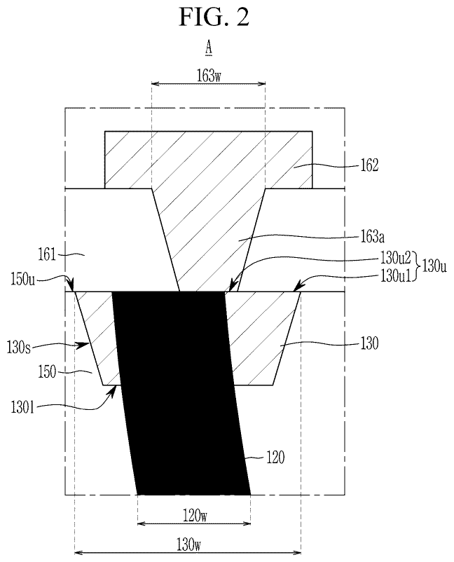

FIG. 2 is an enlarged view of a region A in FIG. 1.

Referring to the drawings, a semiconductor package 100A according to at least one embodiment may include a plurality of semiconductor chips 110 stacked onto each other, conductive wires 120, one or more conductive pad 130, one or more conductive pillar 140, an encapsulant 150, a redistribution structure 160, and a conductive bump 170.

The semiconductor chips 110 may include, for example, a first semiconductor chip 110A, a second semiconductor chip 110B, a third semiconductor chip 110C, and a fourth semiconductor chip 110D sequentially stacked. However, the number of the semiconductor chips 110 included in the semiconductor package 100A is not particularly limited, and the number of the semiconductor chips 110 may be more or less than shown in the drawing. According to at least one embodiment, the semiconductor package 100A may include only a single semiconductor chip 110, for example the first semiconductor chip 110A.

Each of the plurality of semiconductor chips 110 includes one or more connections pad 111, and the connections pad 111 may be arranged in a direction toward the redistribution structure 160. The plurality of semiconductor chips 110 may be stacked so that each connection pad 111 is not covered by other semiconductor chips. The connection pad 111 may include conductive materials, for example copper (Cu), aluminum (Al), gold (Au), silver (Ag), platinum (Pt), tin (Sn), chromium (Cr), Palladium (Pd), lead (Pb), titanium (Ti), tungsten (W), their alloys, and/or the like. In at least some embodiments, a passivation film (not illustrated) may be formed on the surface where the connection pad 111 of the semiconductor chip 110 is disposed, and the passivation film may be formed of photosensitive polyimide (PSPI), for example.

At least one of the semiconductor chips 110 may include a memory chip. The memory chip may, for example, include one or more of a DRAM (Dynamic Random Access Memory) chip, SRAM (Static Random Access Memory) chip, flash (flash) memory chip, an HBM (High Bandwidth Memory) chip, a ROM (Read-Only Memory) chip, a MRAM (Magnetic Random Access Memory) chip, and/or the like.

The semiconductor package 100A may further include adhesive members (AF) that attach the semiconductor chips 110 to each other. For example, the semiconductor package 100A includes an adhesive member placed between the first semiconductor chip 110A and the second semiconductor chip 110B, an adhesive member placed between the second semiconductor chip 110B and the third semiconductor chip 110C, and an adhesive member placed between the third semiconductor chip 110C and the fourth semiconductor chip 110D. The semiconductor chip 110 may be placed on another semiconductor chip with the adhesive member AF attached to at least some regions of the lower surface of the semiconductor chip 110. A die attach film (DAF), for example, may be used as a material for the adhesive member (AF).

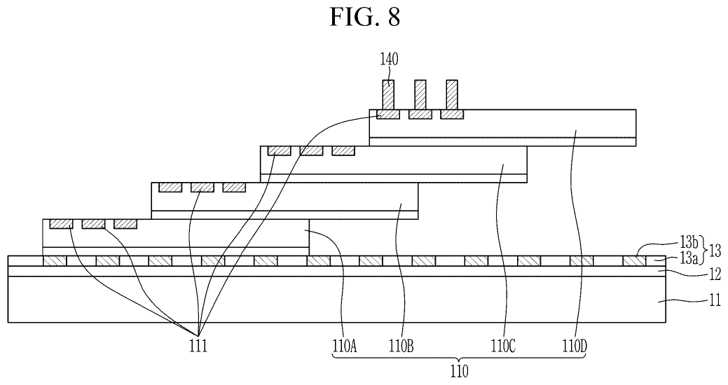

The adhesive member AF may also be placed on the power surface of the first semiconductor chip 110A, (e.g., the lowest side of the semiconductor chips 110). The first semiconductor chip 110A may be placed on the carrier substrate (11, referring to FIG. 8) and fixed on the carrier substrate 11 in the state that the adhesive member is attached to the lower surface of the first semiconductor chip 110A. The adhesive member disposed on the lower surface of the first semiconductor chip 110A may be exposed to the lower surface of the encapsulant 150, or may be covered by another insulating layer formed on the lower surface of the encapsulant 150. Alternatively, the adhesive member placed on the lower surface of the first semiconductor chip 110A may be removed through a grinding, etc., and may not remain in the semiconductor package.

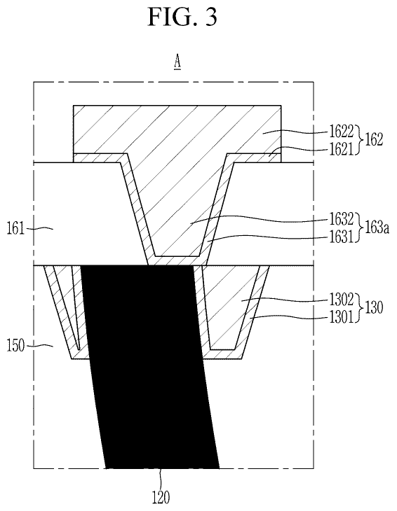

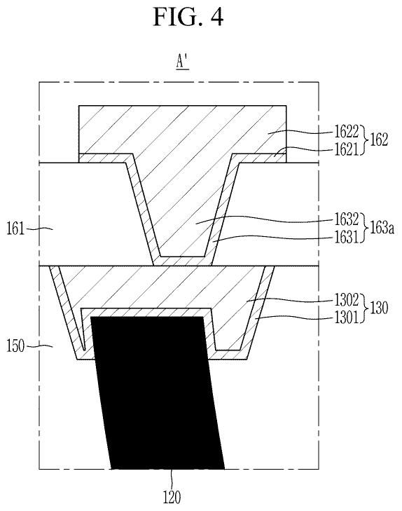

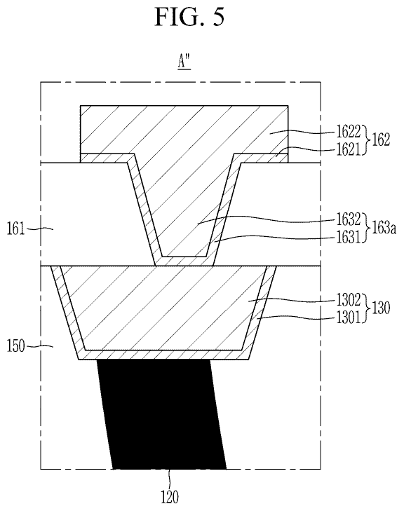

The conductive wire 120 may electrically connect the connection pads 111 of the semiconductor chip 110 and the corresponding conductive pads 130. For example, the conductive wires 120 may each be in contact with each of the connection pad 111 of the semiconductor chip 110 and the conductive pad 130, so that the connection pad 111 of the semiconductor chip 110 and the conductive pad 130 may be connected via the conductive wire 120. The conductive wire 120 may be placed on one surface of the semiconductor chip 110 where the connection pad 111 is disposed, and one end (the lower end of the drawing) of the conductive wire 120 may be bonded to the connection pad 111 of the semiconductor chip 110. The other end (the upper end on the drawing) of the conductive wire 120 may be exposed onto the upper surface 130u of the conductive pad 130 (referring to FIG. 2 and FIG. 3), may be embedded in the conductive pad 130 (referring to FIG. 4), and/or may be in contact with the lower surface 1301 of the conductive pad 130 (referring to FIG. 5). The conductive wire 120 may be made of any conductive material, for example copper (Cu), aluminum (Al), gold (Au), an alloy thereof, and/or the like.

In at least one embodiment, a conductive pillar 140 may be connected to the fourth semiconductor chip 110D placed at the top among the semiconductor chips 110 instead of a conductive wire. The conductive pillar 140 may be connected to the connection pad 111 of the fourth semiconductor chip 110D, so that the fourth semiconductor chip 110D and the redistribution structure 160 may be electrically connected. The upper surface 140u of the conductive pillar 140 may be exposed to the upper surface 150u of the encapsulant 150 by a grinding the encapsulant 150. The conductive pillar 140 may include a conductive material such as copper (Cu), aluminum (Al), and/or the like. The diameter of conductive pillar 140 may be similar to or larger than the diameter of the conductive wire 120. For example, the diameter of the conductive pillar 140 may be approximately 50 μm and/or the thickness may be approximately 40 μm or less, but is not limited thereto.

However, according to at least one embodiment, the fourth semiconductor chip 110D placed at the top of the semiconductor chips 110 may be connected to the redistribution structure 160 through a conductive wire like other semiconductor chips 110A, 110B, and 110C.

In a comparative case, subsequent to the bonding of the wiring, a process may result in the wiring becoming bent and thereby degrading the connection. For example, in a molding process that occurs after vertically bonding the wire to the semiconductor chip, the pressure applied may cause a sweeping phenomenon wherein the wire becomes bent. If the degree of the sweeping of the wire exceeds a process margin, a defective electrical connection of the wire may occur. Particularly, for products with a large number of input/output (I/O) terminals and a small pitch (e.g., 50 micrometers (μm) or less), a wire sweeping control is more important.

In contrast, in the present disclosure, to prevent a poor connection between the conductive wire 120 and the redistribution structure 160 that may occur due to the sweeping of the conductive wire 120, a conductive pad 130 that performs a function of a sweeping compensation pad is introduced into the semiconductor package 100A.

The conductive pad 130 may be connected to the upper end of the conductive wire 120 and may be placed on the redistribution structure 160 to be spaced apart from the semiconductor chip 110 with the conductive wire 120 in between. In at least one embodiment, the conductive pad 130 may also be placed along with the conductive wire 120 on the surface where the connection pad 111 of the semiconductor chip 110 is placed.

Referring to FIG. 2, the conductive pad 130 may be at least partially covered with the encapsulant 150 along with the conductive wire 120. For example, the side surface 130s and the lower surface 1301 of the conductive pad 130 may be covered with the encapsulant 150 and/or may be in direct contact with the encapsulant 150. The upper surface 130u of the conductive pad 130 is not covered with the encapsulant 150, but may be, e.g., exposed onto the upper surface 150u of the encapsulant 150. The central region u2 of the upper surface 130u of the conductive pad 130 may be connected to the redistribution structure 160 by being in contact with the first via 163a, and the edge region 130u1 surrounding the central region 130u2 of the upper surface 130u of the conductive pad 130 may be covered with the insulating layer 161 of the redistribution structure 160.

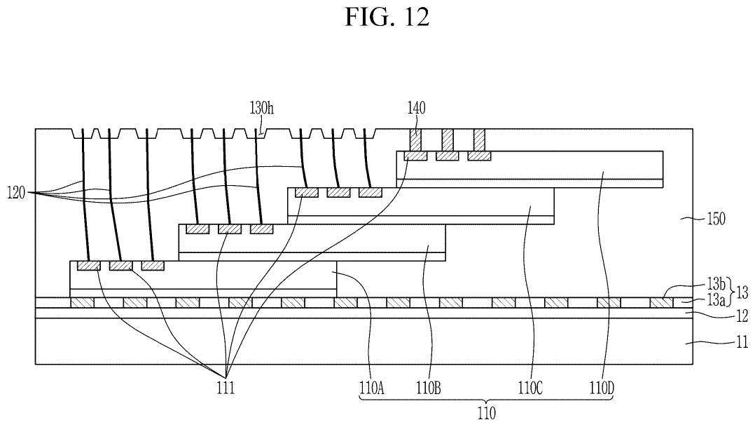

In order to perform the sweeping compensation function, the diameter 130w of the conductive pad 130 may be made larger than the diameter 120w of the conductive wire 120. As will be described later, the position of the conductive pad 130 may be determined based on a sweeping degree data for the conductive wire 120, and may be designed to a more accurate position according to the trend of the sweeping degree of the conductive wire 120. Therefore, the diameter of the conductive pad 130 may be designed so that it is not excessively large, thereby securing the space for the placement of the adjacent conductive pads 130 while preventing (or reducing the potential for) the electric short between the conductive pads 130. For example, the diameter 130w of the conductive pad 130 may be less than or equal to twice the diameter 120w of the conductive wire 120. As a specific example, the diameter 120w of the conductive wire 120 may be about 15 μm or more and about 25 μm or less to suit a high density, high performance package, and/or as a more specific example, about 15 μm or more and about 25 μm or less, and the diameter 130w of the conductive pad 130 may be about 25 μm or more and about 50 μm or less, and/or as a more specific example, about 40 μm. When a groove portion (see FIG. 12) for forming the conductive pad 130 is formed through a laser processing, the diameter of the conductive pad 130 may be reduced in the thickness direction toward the conductive wire 120 in a via 163. If the diameter of the conductive pad 130 is not constant in the thickness direction, the diameter 130w of the conductive pad 130 means the maximum diameter. However, in at least some embodiments, the diameter of the conductive pad 130 may be constant in the thickness direction.

The diameter 130w of the conductive pad 130 may be larger than at least one diameter of vias 163. The diameter 130w of the conductive pad 130 may be larger than the diameter 163w of the corresponding first via 163a contacting the conductive pad 130. For example, the diameter 163w of the first via 163a may be approximately 15 μm or more and approximately 25 μm or less, and/or as a more specific example, approximately 20 μm. If the diameter of the via 163 is not constant in the thickness direction, the diameter of the via 163 means the maximum diameter.

In at least one embodiment, for the sweeping compensation of all conductive wires 120 included in the semiconductor package 100A, the conductive pad 130 is configured in plurality so that each conductive pad 130 may be connected to each conductive wire 120. Therefore, all conductive wires 120 included in the semiconductor package 100A may be connected to the redistribution structure 160 through a corresponding conductive pad 130. However, as described later, in at least some embodiments, some of the conductive wires 120 included in the semiconductor package may be connected to the redistribution structure 160 through the conductive pad 130, and the remaining portions may be directly connected to the redistribution structure 160.

The encapsulant 150 may encapsulates at least a portion of each of the semiconductor chips 110, the conductive pad 130, the conductive wire 120, and the conductive pillar 140. The encapsulant 150 may include an insulating material, for example an epoxy molding compound (EMC). The upper surface 150u of the encapsulant 150 may expose the upper surface 130u of the conductive pad 130 and the upper surface 140u of the conductive pillar 140. For example, the upper surface 150u of the encapsulant 150, the upper surface 130u of the conductive pad 130, and the upper surface 140u of the conductive pillar 140 may be coplanar.

The redistribution structure 160 may be disposed on the encapsulant 150 and may include an insulating layer(s) 161, at least one wiring layer 162, and at least one via 163.

The insulating layer 161 may prevent (or reduce the potential for) an electric short between the conductive pad 130 and the wiring layer 162 and/or between the conductive pillar 140 and the wiring layer 162 and the wiring layers 162. Each wiring layer 162 may be placed on each insulating layer 161. The insulating layers 161 may have boundaries with each other or may not have boundaries that can be confirmed with the naked eye. depending on their materials, the manufacturing processes, etc.

The insulating layer 161 may include an insulating material, for example thermoplastic resin such as polyimide (PI), thermosetting resin such as epoxy, photo-imageable dielectric (PID), etc. If PID is used as the material for insulating layer 161, a fine pattern may be implemented by applying a photo process.

The insulating layer disposed on the lowest side of the insulating layers 161 may be formed directly on the encapsulant 150 and cover the encapsulant 150. The first via 163a may have a fine diameter, and the insulating layer disposed on the lowest side through which the first via 163a penetrates among the insulating layers 161 may cover the edge region u1 of the upper surface 130u of the conductive pad 130 (referring to FIG. 2). Similarly, the second via 163b may have a fine diameter, and the insulating layer disposed at the lowest side may cover the edge region of the upper surface 140u of the conductive pillar 140.

The wiring layer 162 may include a wiring pattern(s), and the wiring patterns may be connected to each other and may perform various functions depending on the design. For example, the wiring layer 162 may include at least one of a signal wire performing a signal transmission function, a power wiring performing a power transmission function, and a ground wiring performing a ground function. The number of the wiring layers 162 is not limited and may be more than shown in the drawing.

Each via 163 may penetrate the insulating layer 161 and connect the conductive pad 130 and the wiring layer 162, the conductive pillar 140 and the wiring layer 162 or the wiring layers 162. Among the vias 163, the via positioned at the lowest side may include a first via 163a, which is in contact with the conductive pad 130 and connects the conductive pad 130 and the wiring layer 162 and a second via 163b that is in contact with the conductive pillar 140 and connects the conductive pillar 140 and the wiring layer 162.

Meanwhile, when forming a wiring layer directly on the encapsulant 150 to be in contact with the conductive pad 130 and the conductive pillar 140, an interface delamination may occur due to low adherence between the wiring layer and the encapsulant 150. In the present disclosure, by connecting the conductive pad 130 and the conductive pillar 140 to the wiring layer 162 through the via 163 with a smaller diameter, the interface delamination may be prevented (or the potential therefor reduced) between the wiring layer and the encapsulant 150, and the semiconductor package with excellent package level and board level reliability may be provided.

The conductive bump 170 may be placed on the redistribution structure 160 and connected to the redistribution structure 160. The conductive bump 170 may be disposed on the redistribution structure 160 to be connected to the redistribution structure 160. The conductive bump 170 may be include or formed of a conductive material, for example a solder. The conductive bump 170 may have various shapes such as a ball and a pin. If necessary, an under bump metal may be additionally disposed between the redistribution structure 160 and the conductive bump 170 to improve the bonding force between them.

FIG. 3 is a detailed view of a region A of FIG. 1.

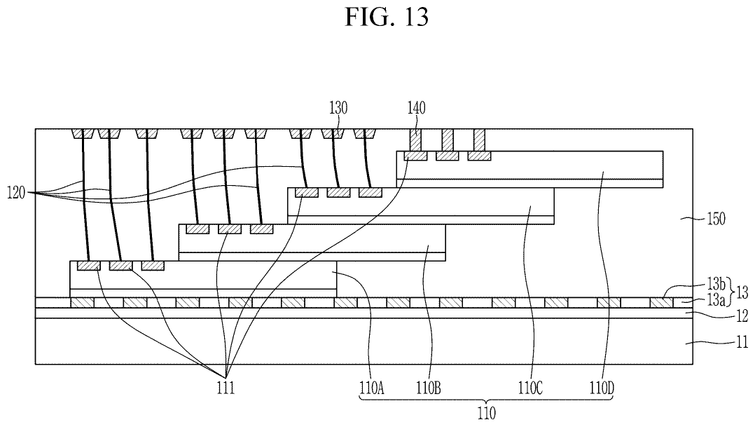

The conductive pad 130 may be formed by forming a groove portion 130h from the upper surface 150u of the encapsulant 150 toward the inside of the encapsulant 150, and filling the groove portion 130h with a conductive material (referring to FIG. 12 and FIG. 13). After forming the groove portion 130h, a thin film region 1301, which is a seed layer, may be formed on the wall and bottom of the groove portion 130h formed in the encapsulant 150 by a physical vapor deposition (PVD), a chemical vapor deposition (CVD), an electroless plating, etc., and a plating process to form a filling region 1302 by an electrolytic plating on the seed layer may be used. Accordingly, the conductive pad 130 may include a filling region 1302 and a thin film region 1301 disposed between the filling region 1302 and the encapsulant 150. The thin film region 1301 may include a plurality of layers including, for example, a titanium (Ti) layer and a copper (Cu) layer, and the filling region 1302 may be formed of, for example, copper (Cu).

In at least one embodiment, when forming the groove portion 130h, by using a laser that does not react the conductive wire 120, but only reacts the encapsulant 150, the region placed within the portion groove 130h of the conductive wire 120 may not be removed. The region disposed within the portion groove 130h of the conductive wire 120 may be embedded in the conductive pad 130 by the plating process. In the plating process, the thin film region 1301 may also be formed on the conductive wire 120, and thus thin film region 1301 may be extended and disposed between the filling region 1302 and the conductive wire 120. According to at least one embodiment, the thin film region 1301 may be formed on at least some regions of the upper surface of the conductive wire 120.

The first via 163a connected to the conductive pad 130 may be manufactured by forming a via hole in the insulating layer 161, forming a thin film region 1631, which is a seed layer, on the wall of the via hole and the conductive pad 130, and forming the filling region 1632 on the seed layer by an electrolytic plating. Accordingly, the first via 163a may include a thin film region 1631 disposed between the filling region 1632 and the insulating layer 161, and between the filling region 1632 and the conductive pad 130. When forming the first via 163a, the wiring layer 162 may be formed together, and the wiring layer 162 may include a thin film region 1621 disposed on the insulating layer 161 and a thick film region 1622 disposed on the thin film region 1621. The thin film regions 1621 and 1631 may include a plurality of layers including a titanium (Ti) layer and a copper (Cu) layer, and the thick region 1622 and the filling region 1631 may be formed of copper (Cu).

FIG. 4 is a detailed view based on another example variation of a region A of FIG. 1.

In an example variation, when forming the groove portion 130h, at least a portion of the region disposed within the groove portion 130h of the conductive wire 120 may be removed by using a laser that reacts with both the conductive wire 120 and the encapsulant 150. For example, after forming the groove portion 130h, some of the regions disposed within the groove portion 130h of the conductive wire 120 may be removed and the remaining portions may remain, and the remaining regions within the groove portion 130h may be buried in the conductive pad 130. The top of the conductive wire 120, which is the region remaining within the groove portion 130h, and the side adjacent thereto may be covered with the thin film region 1301 of the conductive pad 130. However, the examples are not limited thereto, and, for example, in at least some embodiments, the thin film region 1301 may be omitted.

FIG. 5 is a detailed view according to another example variation of a region A in FIG. 1.

In another example variation, when forming the groove portion 130h, the entire region disposed within the groove portion 130h of the conductive wire 120 may be removed by using a laser in which both the conductive wire 120 and the encapsulant 150 react. The top of the conductive wire 120 exposed onto the encapsulant 150 may be covered with the thin film region 1301 of the conductive pad 130. Though the example illustrated the conductive pad 130 including the thin film region 1301, the examples are not limited thereto, and, for example, in at least some embodiments, the thin film region 1301 may be omitted.

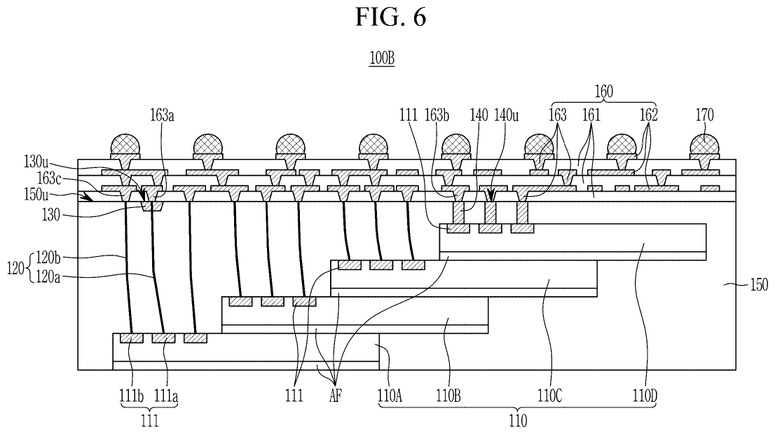

FIG. 6 is a cross-sectional view of a semiconductor package according to at least one embodiment.

Referring to the drawing, in a case of a semiconductor package 100B according to at least one embodiment, only a portion of the conductive wire 120 connected to the connection pad 111 of the semiconductor chip 110 is in contacts with the conductive pad 130.

In the following description, the conductive wire in contact with the conductive pad 130 is referred to as a first conductive wire 120a, and the conductive wire that does not contact the conductive pad 130 is referred to as a second conductive wire 120b. Additionally, the connection pad 111 connected to the first conductive wire 120a is referred to as a first connection pad 111a, and the connection pad 111 connected to the second conductive wire 120b is referred to as a second connection pad 111b.

The second conductive wire 120b may connect the second connection pad 111b and the redistribution structure 160. The second conductive wire 120b may exposed to the upper surface 150u of the encapsulant 150 and be directly connected to the redistribution structure 160. For example, the second conductive wire 120b may be connected to the redistribution structure 160 by contacting the third via 163c of the redistribution structure 160.

In a case of a semiconductor package 100B according to at least one embodiment, a conductive pad 130 is introduced to selectively perform the sweeping compensation function on the conductive wire 120a with a severe degree (and/or greater likelihood) of the sweeping. If conductive pad 130 is introduced selectively, the size of the conductive pad 130 may be increased and an additional process margin may be secured. For example, among the semiconductor chips 110, the first semiconductor chip 110A placed on the lowest side is far from the redistribution structure 160, and then may be connected to the redistribution structure 160 through the long conductive wire 120. Therefore, some or all of the conductive wires 120 connected to the first semiconductor chip 110A may have a severe likelihood of the sweeping occurring, and thereby the conductive pads 130 may be introduced for the sweeping compensation.

In an example embodiment, some of the conductive wires 120 connected to at least one semiconductor chip 110 among the semiconductor chips 110 of the semiconductor package 100B may be connected to the redistribution structure 160 through the conductive pad 130, and the remaining portions may be directly connected to the redistribution structure 160. That is, at least one of the semiconductor chips 110 of the semiconductor package 100B may include a first connection pad 111a connected to the first conductive wire 120a and a second connection pad 111b connected to the second conductive wire 120b. For example, as shown in the drawing, the first semiconductor chip 110A disposed on the lowest side may include the first connection pad 111a connected to the first conductive wire 120a and the second connection pad 111b connected to the second conductive wire 120b. As another example, the wire-bonded first semiconductor chip 110A, second semiconductor chip 110B, and third semiconductor chip 110C may all include the first connection pad 111a connected to the first conductive wire 120a and the second connection pad 111b connected to the second conductive wire 120b.

In another example embodiment, among the wire bonded semiconductor chips 110 of the semiconductor package 100B, the conductive wires 120 connected to some semiconductor chip(s) may be connected to the redistribution structure 160 through the conductive pad 130, and the conductive wires 120 connected to the remaining semiconductor chip(s) may be directly connected to the redistribution structure 160. For example, the conductive wires 120 connected to the first semiconductor chip 110A placed on the lowest side may be connected to the redistribution structure 160 through the conductive pad 130, and the conductive wires 120 connected to the remaining wire-bonded semiconductor chips 110B and 110C may be directly connected to the redistribution structure 160.

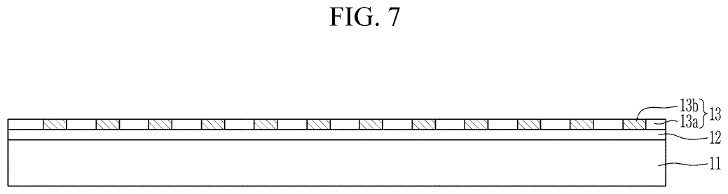

FIG. 7 to FIG. 15 are views showing a manufacturing process of a semiconductor package according to at least one embodiment.

According to at least one embodiment, the semiconductor package manufacturing method may include stacking a plurality of semiconductor chips 110 each including a connection pad 111, connecting a conductive wire 120 to at least one connection pad 111 among the plurality of semiconductor chips 110, encapsulating the plurality of semiconductor chips 110 and the conductive wire 120 with an encapsulant 150, exposing the conductive wire 120 by grinding the encapsulant 150, forming a groove portion 130h exposing the conductive wire 120 and being toward the inside of the encapsulant 150 from the upper surface 150u of the encapsulant 150, forming a conductive pad 130 filling the groove portion 130h and connected to the conductive wire 120, and forming a redistribution structure 160 on the encapsulant 150.

First, referring to FIG. 7 and FIG. 8, a carrier substrate 11 is prepared, and a plurality of semiconductor chips 110 each including a connection pad 111 is stacked on the carrier substrate 11. The semiconductor chips 110 may be placed on the carrier substrate 11 in the stacked state, or may be sequentially stacked on the carrier substrate 11.

The carrier substrate 11 may be a glass substrate, a silicon substrate, etc. On the carrier substrate 11, one or more of a release layer 12 for removing the carrier substrate 11 and an alignment layer 13 for providing a align position of the semiconductor chips 110 may be disposed. The alignment layer 13 may include an insulating layer (e.g., a polyimide layer) 13a and metal patterns (e.g., copper patterns) 13b.

Each semiconductor chip 110 may be attached to the carrier substrate 11 or to another semiconductor chip 110 through an adhesive member (AF). For example, the first semiconductor chip 110A may be placed on the carrier substrate 11 with a state that an adhesive member is attached to the bottom of the first semiconductor chip 110A and attached to the carrier substrate 11. As another example, the second semiconductor chip 110B may be placed on the first semiconductor chip 110A with a state that an adhesive member is attached to the bottom of the second semiconductor chip 110B and attached to the first semiconductor chip 110A.

In at least some embodiments, at least one conductive pillar 140 may be formed in the fourth semiconductor chip 110D, which is placed at the uppermost side of the semiconductor chips 110.

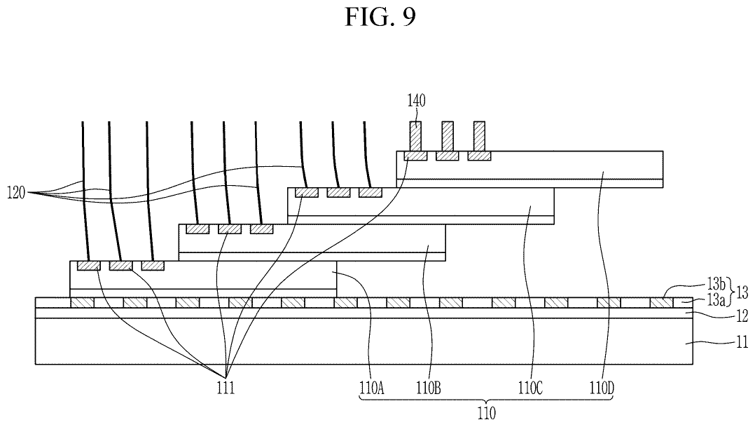

Next, referring to FIG. 9, the conductive wire 120 is connected to at least one connection pad 111 among the plurality of semiconductor chips 110. For example, the conductive wire 120 may be connected to the connection pads 111 of each of the first semiconductor chip 110A, the second semiconductor chip 110B, and the third semiconductor chip 110C to which the conductive pillar 140 is not connected among the plurality of semiconductor chips 110.

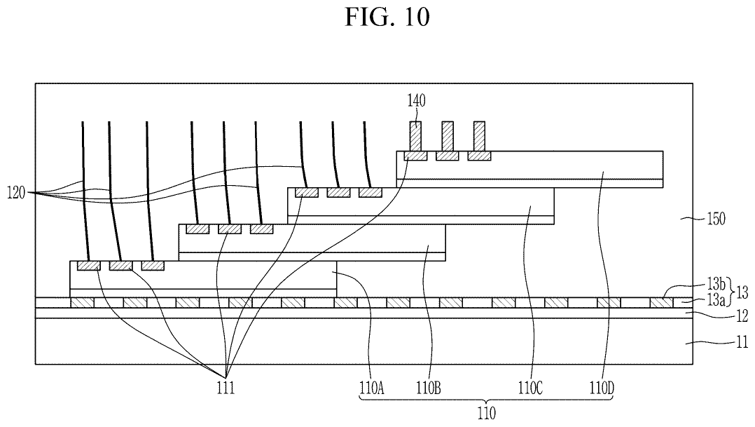

Next, referring to FIG. 10, plurality of semiconductor chips 110 and the conductive wire 120 are encapsulated with the encapsulant 150. At this time, the conductive wire 120 may be embedded within the encapsulant 150. The encapsulant 150 may be formed through a compression molding, a transfer molding, etc.

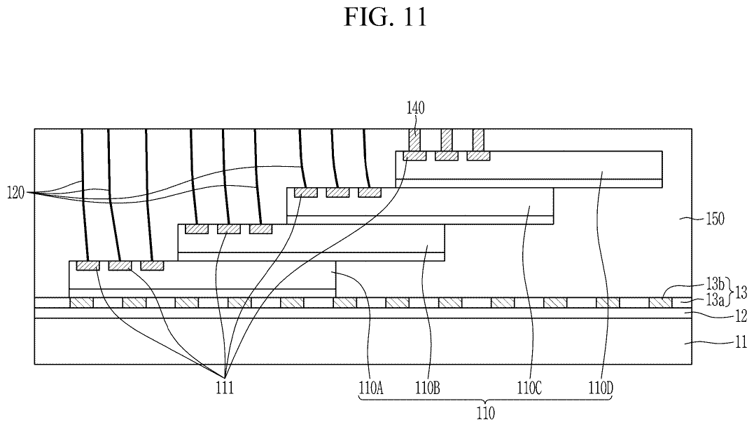

Next, referring to FIG. 11, the encapsulant 150 is grinded to expose the conductive wire 120 and the conductive pillar 140. When grinding, the parts of the conductive wire 120 and the conductive pillar 140 may be removed by the grinding.

Meanwhile, when designing the conductive pad 130, the sweeping degree of the conductive wire 120 may be measured, the measured sweeping degree may be converted into a data (forming a sweeping mapping data), and the position of the conductive pad 130 may be determined based on the data. The measurement of the sweeping degree of the conductive wire 120 may be performed cumulatively for all manufactured products, may be performed for a few (e.g., 2000 and/or 5000) products, and/or may be performed for separate test products.

In order to determine the position of the conductive pad 130 based on the data sweeping degree, the manufacturing method of the semiconductor package according to at least one embodiment may further include measuring the degree of the sweeping of the conductive wire 120 and determining the position of the conductive pad 130 based on the measured degree of the sweeping by recognizing the conductive wire 120 exposed by the encapsulant 150 with a vision and comparing the exposed position of the conductive wire 120 with the designed position. The vision recognition of the conductive wire 120 may be performed through a mono camera for example. When determining the position of the conductive pad 130, an affine transformation including a translation, a rotation, a scaling, a reflection, and a shear may be used.

Next, referring to FIG. 12, from the upper surface 150u of the encapsulant 150 toward the inside of the encapsulant 150, a groove portion 130h exposing the conductive wire 120 is formed. Forming the groove portion 130h may be performed by a laser processing. During the laser processing, the groove portion 130h may be formed so that its diameter decreases in a direction from the upper surface 150u of the encapsulant 150 toward the inside of the encapsulant 150.

In at least one embodiment, when forming the groove portion 130h, the region disposed within the groove portion 130h of the conductive wire 120 may not be removed by using a laser that does not react with the conductive wire 120 and only reacts with the encapsulant 1.5. Therefore, after forming the groove portion 130h, the region disposed within the groove portion 130h of the conductive wire 120 may remain (referring to FIG. 3).

In at least one embodiment, when forming the groove portion 130h, at least a portion of the region disposed within the groove portion 130h of the conductive wire 120 may be removed by using a laser that reacts with both the conductive wire 120 and the encapsulant 150 (referring to FIG. 4 and FIG. 5).

Next, referring to FIG. 13, while filling the groove portion 130h a conductive pad 130 connected to the conductive wire 120 is formed. The conductive pad 130 may be manufactured by forming a thin film region 1301, which is a seed layer, on the wall and bottom of the groove portion 130h formed in the encapsulant 150 by a physical vapor deposition (PVD), a chemical vapor deposition (CVD), an electroless plating, etc., and forming filling region 1302 on the seed layer thorough an electrolytic plating (referring to FIG. 3). In at least some embodiments, the filling of the groove portion 130h may include forming preliminary layers and removing portions thereof to form the thin film region 1301 and/or the filling region 1302. In order to perform the sweeping compensation function, the diameter of the groove portion 130h and the conductive pad 130 may be formed larger than each diameter of the via 163 of the conductive wire 120 and of the redistribution structure 160.

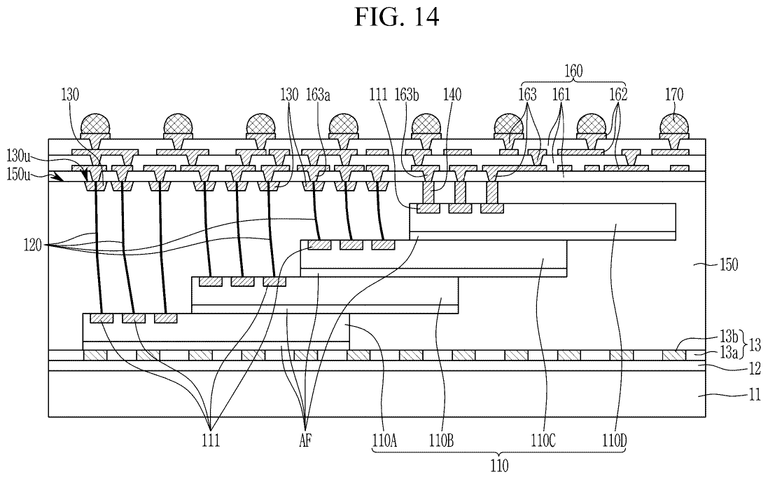

Next, referring to FIG. 14, a redistribution structure 160 is formed on the encapsulant 150. The redistribution structure 160 may be electrically connected to the semiconductor chip 110 through one or more of the conductive pad 130, the conductive wire 120, and the conductive pillar 140. The redistribution structure 160 may be formed by repeatedly forming an insulating layer 161 on the for example encapsulant 150, forming a via 163 penetrating the insulating layer 161, and forming a wiring layer 162 connected to the via 163 on the insulating layer 161.

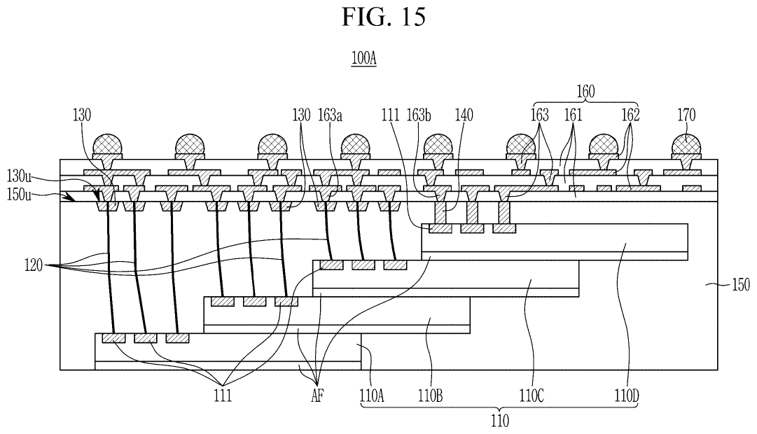

Finally, referring to FIG. 15, the carrier substrate 11, the release layer 12, and the alignment layer 13 may be removed to manufacture a semiconductor package 100A. If necessary, the insulating layer 13a of the alignment layer 13 may remain in the semiconductor package and cover the adhesive member AF attached to the bottom of the first semiconductor chip 110A.

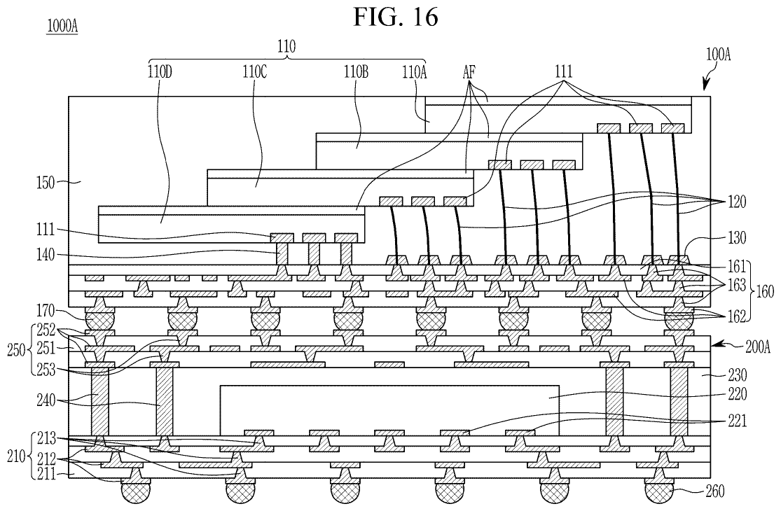

FIG. 16 is a cross-sectional view of a package on package including a semiconductor package according to at least one embodiment.

Referring to the drawing, a package on package 1000A may include a first semiconductor package 100A and a second semiconductor package 200A.

The first semiconductor package 100A may be a semiconductor package according to at least one embodiment and be placed on the second semiconductor package 200A and electrically connected to the second semiconductor package 200A.

The second semiconductor package 200A may include a first redistribution structure 210, a semiconductor chip 220 paced on the first redistribution structure 210, an encapsulant 230, which encapsulates at least part of the semiconductor chip 220, a second redistribution structure 250 placed on the encapsulant 230, a conductive pillar 240 that penetrates the encapsulant 230 and connects the first redistribution structure 210 and the second redistribution structure 250, and a conductive bump 260 placed on the lower surface of the first redistribution structure 210.

The first redistribution structure 210 may include at least one insulating layer 211, at least one wiring layer 212, and at least one via 213. The first redistribution structure 210 may be formed by a chip first method in which the first redistribution structure 210 is formed by encapsulating the semiconductor chip 220 with the encapsulant 230, but it is not limited thereto.

The semiconductor chip 220 may be placed on the first redistribution structure 210 and electrically connected to the first redistribution structure 210. The semiconductor chip 220 may be placed directly on the first redistribution structure 210 to be in contact, or may be placed on the first redistribution structure 210 through a conductive bump (e.g., a solder bump). The semiconductor chip 220 includes a connection pad 221, and may be arranged in a face down type so that the surface on which the connection pad 221 is placed faces the first redistribution structure 210.

The semiconductor chip 220 may include a logic chip for example. For example, the logic chip may include one or more of an application processor (AP), a microprocessor (micro-processor), a central processing unit (CPU), or an application specific integrated circuit (ASIC).

The encapsulant 230 encapsulates at least a portion of the semiconductor chip 220 on the first redistribution structure 210. The material of the encapsulant 230 may be an insulating material, for example an epoxy molding compound (EMC).

The second redistribution structure 250 may include an insulating layer(s) 251, a wiring layer(s) 252, and a via(s) 253. The space between the second redistribution structure 250 and the semiconductor chip 220 may be filled with an encapsulant 230.

The conductive pillar 240 may be formed of a conductive material, for example copper (Cu). The conductive pillar 240 may have various shapes such as a pillar and a ball.

The conductive bump 260 may connect a package on package 1000A with other components such as a substrate. The conductive bump 260 may be placed on the lower surface of the first redistribution structure 210 and connected to the first redistribution structure 210. The conductive bump 260 may be formed of a conductive material, for example a solder.

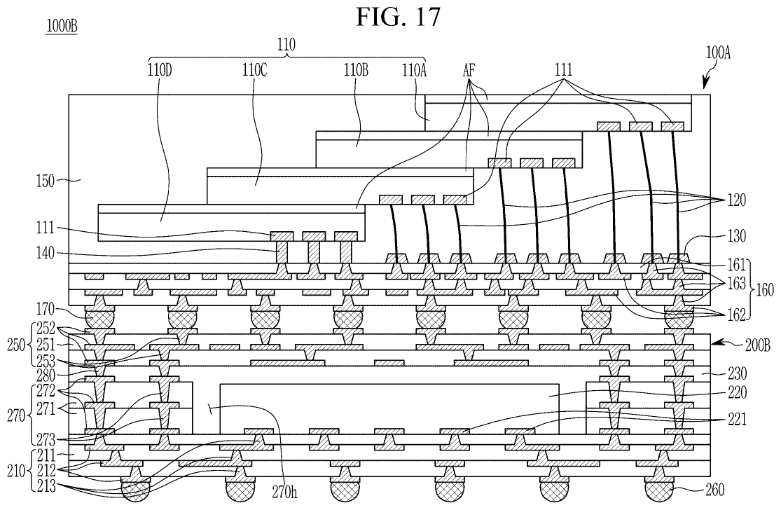

FIG. 17 is a cross-sectional view of another package on package including a semiconductor package according to at least one embodiment.

Referring to the drawing, a package on package 1000B may include a first semiconductor package 100A and a second semiconductor package 200B.

The first semiconductor package 100A may be a semiconductor package according to at least one embodiment and be placed on the second semiconductor package 200B and electrically connected to the second semiconductor package 200B.

In the second semiconductor package 200B, compared to the case of the second semiconductor package 200A in FIG. 16, the first redistribution structure 210 and the second redistribution structure 250 are connected through the core substrate 270 instead of the conductive pillar 240.

The core substrate 270 may include at least one insulating layer 271, at least one wiring layer 272, and at least one via 273, and may have a penetration hole 270h. The semiconductor chip 220 may be disposed within the penetration hole 270h of the core substrate 270, and the encapsulant 230 may fill at least a portion of the penetration hole 270h and may extend onto the core substrate 270.

In addition, the second semiconductor package 200B may further include a via 280 that penetrates the encapsulant 230 on the core substrate 270 and electrically connects the core substrate 270 and the second redistribution structure 250.

The package on package 1000B may have an increased wiring space through a core substrate 270.

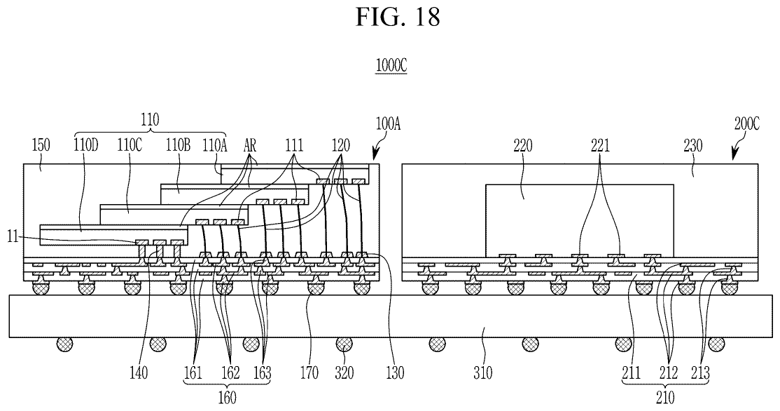

FIG. 18 is a cross-sectional view of another package on board including a semiconductor package according to at least one embodiment.

Referring to the drawing, the package on board 1000C may include a first semiconductor package 100A and a substrate 310 on which the first semiconductor package 100A is placed. On the substrate 310, a second semiconductor package 200C may be placed along with the first semiconductor package 100A.

The first semiconductor package 100A may be a semiconductor package according to at least one embodiment and be placed on the substrate 310 and electrically connected to the substrate 310.

The second semiconductor package 200C, compared to the case of the second semiconductor package 200A in FIG. 16, may do not include the second redistribution structure 250 and the conductive pillar 240.

The substrate 310 may be an interposer substrate that electrically connects the first semiconductor package 100A and the second semiconductor package 200C, and may be mounted on a separate package substrate. A conductive bump 320 may be placed on the bottom of the substrate 310 for connection to other components such as a package substrate. The conductive bump 320 may be formed from a conductive material, for example a solder.

While this disclosure has been described in connection with what is presently considered to be a practical example embodiment, it is to be understood that the disclosure is not limited to the disclosed embodiment, but, on the contrary, is intended to cover various modifications and equivalent arrangements included within the spirit and scope of the appended claims.

Additionally, the embodiments of the present disclosure are not independent of each other and may be practiced in a combination with each other unless specifically contradictory. Therefore, embodiments that combine embodiments of the present disclosure should also be considered included in the present disclosure.

What is claimed is:

1. A semiconductor package comprising:
a semiconductor chip including a connection pad;
a conductive pad over the semiconductor chip, the conductive pad spaced apart from the semiconductor chip;
a conductive wire electrically connecting the connection pad of the semiconductor chip with the conductive pad;
an encapsulant encapsulating at least a portion of the semiconductor chip, the conductive pad, and the conductive wire; and
a redistribution structure on the encapsulant, the redistribution structure including a via and a wiring layer, the via electrically contacting the conductive pad and the wiring layer electrically contacting the via,
wherein a diameter of the conductive pad is larger than a diameter of the conductive wire and a diameter of the via.

2. The semiconductor package of claim 1, wherein an upper surface of the conductive pad is exposed to an upper surface of the encapsulant.

3. The semiconductor package of claim 2, wherein a side surface and a lower surface of the conductive pad are in contact with the encapsulant.

4. The semiconductor package of claim 3, wherein the conductive pad includes a filling region and a thin film region, the thin film region between the filling region and the encapsulant.

5. The semiconductor package of claim 4, wherein the thin film region separates the filling region from the conductive wire.

6. The semiconductor package of claim 1, wherein the conductive wire is partially embedded in the conductive pad.

7. The semiconductor package of claim 1, wherein the diameter of the conductive pad decreases with distance from the via toward the conductive wire.

8. The semiconductor package of claim 1, wherein the diameter of the conductive pad is less than or equal to twice the diameter of the conductive wire.

9. The semiconductor package of claim 1, wherein
the redistribution structure further includes an insulating layer covering the encapsulant and on which the wiring layer is disposed, and
the via penetrates the insulating layer and electrically connects the conductive pad to the wiring layer.

10. A semiconductor package comprising:
a stack of semiconductor chips, the stack of semiconductor chips including a first semiconductor chip on the lowest side of the stack of semiconductor chips, the first semiconductor including a first connection pad;
a conductive pad over the stack of semiconductor chips such that the conductive pad is spaced apart from the first semiconductor chip;
a first conductive wire electrically connecting the first connection pad and the conductive pad;
an encapsulant encapsulating at least a portion of each of the stack of semiconductor chips, the conductive pad, and the first conductive wire; and
a redistribution structure on the encapsulant, the redistribution structure including a first via in electrical contact with the conductive pad and a wiring layer electrically connected to the first via,
wherein a diameter of the conductive pad is larger than a diameter of the first conductive wire and a diameter of the first via.

11. The semiconductor package of claim 10, wherein
the first semiconductor chip further includes a second connection pad,
the semiconductor package further includes a second conductive wire electrically connecting the second connection pad and the redistribution structure, and
wherein the second conductive wire is exposed to an upper surface of the encapsulant.

12. The semiconductor package of claim 11, wherein an upper surface of the conductive pad is exposed to the upper surface of the encapsulant.

13. The semiconductor package of claim 10, further comprising:
a conductive pillar electrically connecting the redistribution structure to a semiconductor chip at the uppermost side of the stack of semiconductor chips.

14. The semiconductor package of claim 13, wherein
the redistribution structure further includes a second via in electrical contact with the conductive pillar and to the wiring layer.

15. The semiconductor package of claim 10, wherein
at least one of the stack of semiconductor chips includes a memory chip.

16. A manufacturing method of a semiconductor package comprising:
stacking a plurality of semiconductor chips, each including a connection pad;
connecting a conductive wire to at least one connection pad among the plurality of semiconductor chips;
encapsulating the plurality of semiconductor chips and the conductive wire with an encapsulant;
exposing the conductive wire by grinding the encapsulant;
forming a groove portion extending from an upper surface of the encapsulant towards an inside of the encapsulant;
forming a conductive pad filling the groove portion such that the conductive pad is electrically connected to the conductive wire; and
forming a redistribution structure on the encapsulant, the redistribution structure including a via in electrical contact with the conductive pad and a wiring layer in electrical contact with the via,
wherein a diameter of the conductive pad is larger than a diameter of the conductive wire and a diameter of the via.

17. The manufacturing method of the semiconductor package of claim 16, further comprising:
determining a degree of sweeping of the conductive wire by comparing the conductive wire exposed to the encapsulant with a designed position of the conductive wire; and
determining a position of the conductive pad based on the determined degree of the sweeping.

18. The manufacturing method of the semiconductor package of claim 16, wherein
forming the groove portion includes laser processing.

19. The manufacturing method of the semiconductor package of claim 16, wherein
a region of the conductive wiring remains within the groove portion after forming the groove portion.

20. The manufacturing method of the semiconductor package of claim 16, wherein
at least a portion of the conductive wiring within the groove portion is removed during the forming the groove portion.
